(19) United States
(12) Patent Application Publication
(10) Pub. No.: US 2011/0056670 A1
(43) Pub. Date: Mar. 10, 2011

(54) HEAT SINK

(76) Inventors: George Anthony Meyer, IV, San Jose, CA (US); Chien-Hung SUN, Zhongli City (TW); Chieh-Ping CHEN, Zhongli City (TW)

(21) Appl. No.: 12/554,851

(22) Filed: Sep. 4, 2009

(51) Int. Cl. H05K 7/20; F28F 7/00

(52) U.S. Cl. 165/185; 165/122

(57) ABSTRACT

A heat sink includes a frame, a vapor chamber fixed to the frame, and a heat-dissipating plate adhered to one surface of the vapor chamber. The heat-dissipating plate has a first heat-dissipating fins region and a second heat-dissipating fins region. The first heat-dissipating fins region and the second heat-dissipating fins region are composed of a plurality of first heat-dissipating fins and a plurality of second heat-dissipating fins that are arranged at intervals, respectively. The pitch of the first heat-dissipating fins in the first heat-dissipating fins region is smaller than that of the second heat-dissipating fins in the second heat-dissipating fins region. By this arrangement, airflow can flow freely among the respective heat-dissipating fins. The first heat-dissipating fins region is used to dissipate a great amount of heat, while the second heat-dissipating fins region is used to exhaust the air rapidly. Thus, the heat-dissipating efficiency can be increased.

### BACKGROUND OF THE INVENTION

1. Field of the Invention

The present invention relates to a heat sink, and in particular to a heat sink for dissipating the heat generated by various electronic products.

2. Description of Prior Art

With the advancement of modern computer information, the working speed of electronic products such as CPU, IC element, power chip, power supply or the like increases so fast that they will generate a large amount of heat in high-speed operation. If the heat is not dissipated timely, the normal operation of the electronic products will be affected, which may reduce the operating performance, cause the hardware to suffer damage, and shorten their lifetime. In order to solve the problem that the electronic elements may be overheated, a common solution is to mount aluminum-extruded heat-dissipating fins on a heat-generating source. The heat-dissipating fins conduct the heat to the outside, and a fan is used to generate compulsory convection of air to increase the heat conduction. Thus, the heat-dissipating effect can be achieved, and the normal working temperature of the electronic device can be maintained.

The heat-dissipating fins are commonly made by extruding aluminum materials. However, due to the limitation in the technology of molds and the pressing process, the thus-made fins are arranged densely in one direction with identical intervals. Thus, the airflow is divided by each fin and can be flown between the respective fins. The wide-and-thick fins enlarge the surface area blocking airflow, as a result of which the air having absorbed heat may not be exhausted rapidly. Thus, a great amount of hot air is still accumulated in the lower portion of the fins, so that the hot air cannot be heat-exchanged with the cooler air on the upper portion of the fins. Therefore, the heat-conducting speed is so slow as to affect the heat-dissipating effect.

Therefore, in order to overcome the above problems, the present Inventor proposes a reasonable and novel structure based on his delicate researches and expert experiments.

### SUMMARY OF THE INVENTION

The present invention is to provide a heat sink, in which airflow can flow freely among the respective heat-dissipating fins. The small pitch region formed in the respective heat-dissipating fins is used to dissipate a great amount of heat, while the large pitch region formed in the respective heat-dissipating fins is used to exhaust the air rapidly.

The present invention is to provide a heat sink, which includes a frame; a vapor chamber fixed to the frame; and a heat-dissipating plate adhered to one surface of the vapor chamber. The heat-dissipating plate has a first heat-dissipating fins region and a second heat-dissipating fins region. The first heat-dissipating fins region and the second heat-dissipating fins region are constituted of a plurality of first heat-dissipating fins and a plurality of second heat-dissipating fins that are arranged at intervals. The pitch of the first heat-dissipating fins in the first heat-dissipating fins region is smaller than that of the second heat-dissipating fins in the second heat-dissipating fins region.

The present invention has advantageous effects as follows. The first heat-dissipating fins region has a plurality of first heat-dissipating fins that are distributed densely, while the second heat-dissipating fins region has a plurality of second heat-dissipating fins that are distributed sparsely. The outside of the first heat-dissipating fins region is connected to a fan. The first heat-dissipating fins region is used as an intake end, while the second heat-dissipating fins region is used as an exhaust end. The first heat-dissipating fins region having a small pitch of the respective first heat-dissipating fins forms a large contact area for air, so that the air can absorb the heat enough to conduct a large amount of heat to the outside. The second heat-dissipating fins region having a large pitch of the respective second heat-dissipating fins forms large air passages for exhausting hot air rapidly. By this arrangement, the heat-dissipating plate has a plurality of heat-dissipating fins with different densities, whereby the heat-dissipating efficiency can be increased.

### BRIEF DESCRIPTION OF THE DRAWINGS

FIG. 1 is an exploded perspective view of the present invention;

FIG. 2 is an assembled perspective view of the present invention;

FIG. 3 is a top view of the present invention;

FIG. 4 is a schematic view showing that the fan enhances the airflow according to the present invention; and

FIG. 5 is a schematic view showing an integrally-formed heat-dissipating plate according to the present invention.

### DETAILED DESCRIPTION OF THE INVENTION

The characteristics and technical contents of the present invention will be explained in more detail with reference to the accompanying drawings. However, the drawings are illustrative only but not used to limit the present invention.

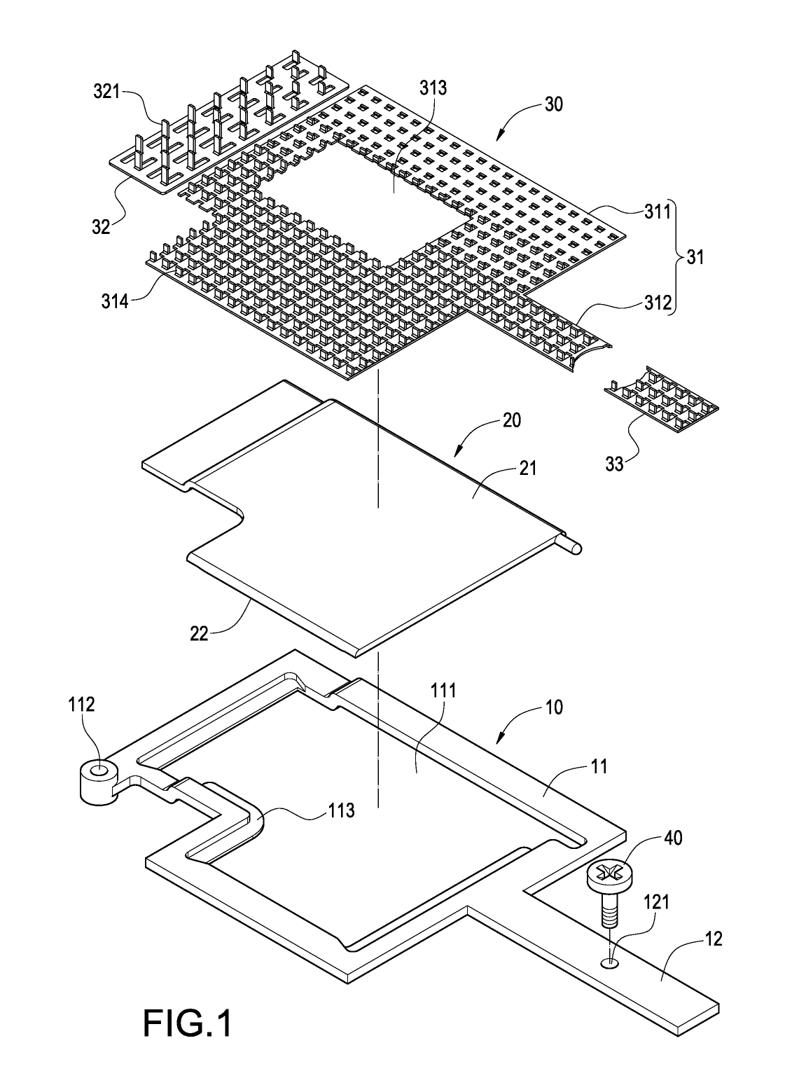

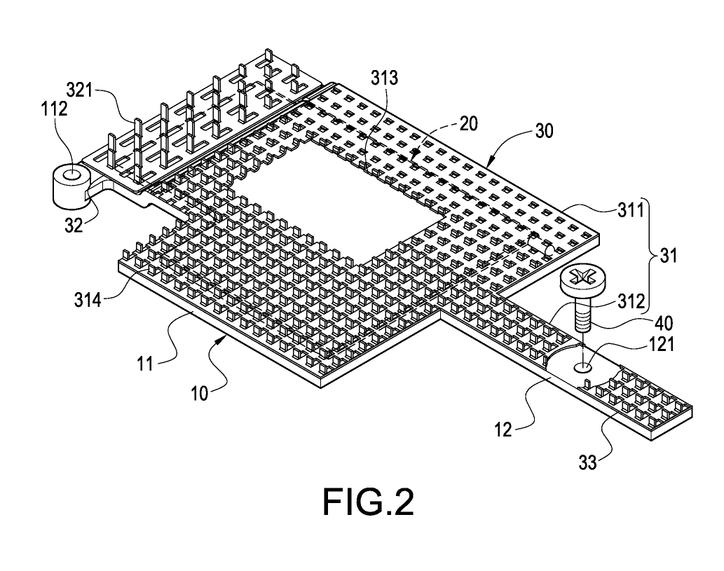

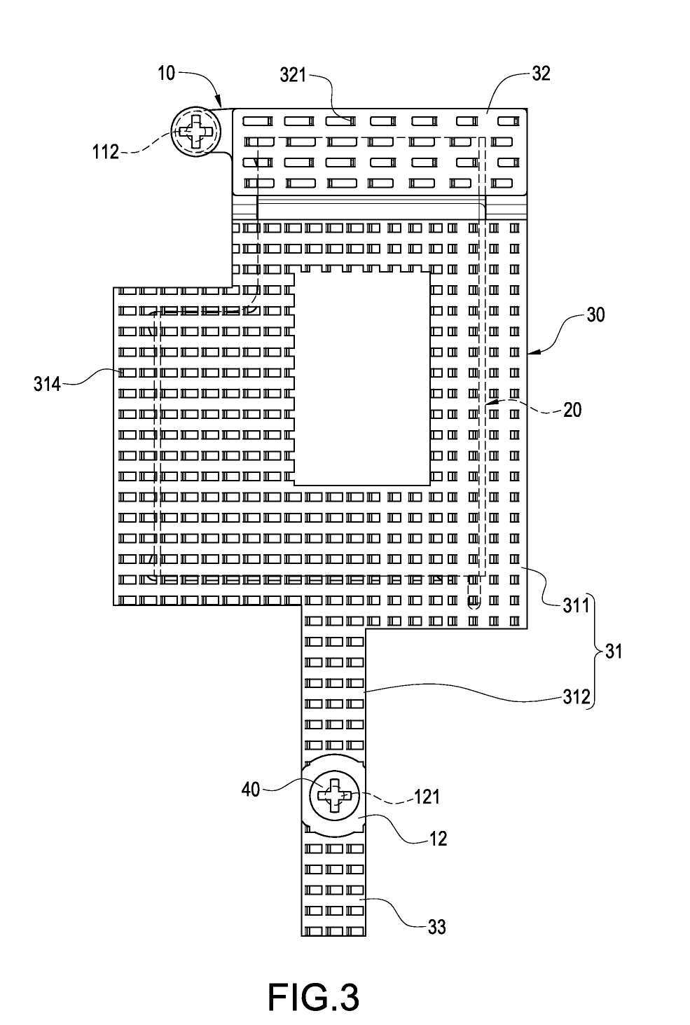

Please refer to FIGS. 1 to 3. The present invention provides a heat sink, which includes a frame 10, a vapor chamber 20 and a heat-dissipating plate 30.

The frame 10 comprises a rim 11 and an elongate plate 12 extending from the outer edge of the rim 11. The rim 11 is provided with a hollow portion 111 and a first through-hole 112. The bottom edge of the rim 11 extends inward to form a plurality of supporting plates 113. The elongate plate 12 is provided with a second through-hole 121.

The vapor chamber 20 comprises an upper surface 21 and a lower surface 22 formed on the other side of the upper surface 21. The vapor chamber 20 is embedded into the hollow portion 111 with its lower surface 22 being adhered to each supporting plate 113. The inner walls of the vapor chamber 20 form a sealed thin casing in which a capillary structure is distributed. The interior of the vapor chamber 20 forms a vacuum accommodating space in which a working fluid is filled. When the lower surface 22 is brought into contact with a heat-generating element to raise its temperature, the working fluid in the accommodating space absorbs sufficient heat to induce a phase change from liquid state to vapor state. The high-temperature vapor flows to the low-temperature upper portion of the casing to release heat. Then, the heat is conducted to the heat-dissipating piece. Thereafter, the vapor is subjected to a phase change to liquid state and then flows to the lower portion of the casing. By the continuous circulation of the working fluid, the waste heat generated by the heat-generating element can be taken away.

The heat-dissipating plate 30 is made of metals having good heat conductivity such as aluminum or copper. The heat-dissipating plate 30 comprises a first heat-dissipating fins region 31 and a second heat-dissipating fins region 32 adjacent to the first heat-dissipating fins region 31. The first heat-dissipating fins region 31 and the second heat-dissipating fins region 32 are formed separately. By a press-forming process, the first heat-dissipating fins region 31 is formed with a plurality of first heat-dissipating fins 314 that protrude upwards and are arranged at intervals. By a press-forming process, the second heat-dissipating fins region 32 is formed with a plurality of second heat-dissipating fins 321 that protrude upwards and are arranged at intervals. The first heat-dissipating fins region 31 and the second heat-dissipating fins region 32 are located on the same one heat-dissipating passage.

The pitch and height of the respective first heat-dissipating fins 314 of the first heat-dissipating fins region 31 are smaller than those of the second heat-dissipating fins 321 of the second heat-dissipating fins region 32. Furthermore, the heights of the respective first heat-dissipating fins 312 and the heights of the respective second heat-dissipating fins 321 decrease gradually from the front side of the heat-dissipating plate 30 towards its rear side. The gradual decrease in height can cooperate with the elements other than the heat-dissipating device in terms of space.

The first heat-dissipating fins region 31 comprises 1 main body 311 and a rear fin 312 extending from an outer edge of the main body 311. The main body 311 is provided with an opening 313 for cooperating with the elements other than the heat-dissipating device in terms of space. The heat-dissipating plate 30 further comprises a third heat-dissipating fins region 33. The second heat-dissipating fins region 32 and the main body 311 are adhered to the upper surface of the vapor chamber 20 and the rim 11. The third heat-dissipating fins region 33 and the rear fin 312 are adhered to the elongate plate 12. The second through-hole 121 is located between the third heat-dissipating fins region 33 and the rear fin 312.

Two screws 40 penetrate the first through-hole 112 and the second through-hole 121 respectively. In this way, the heat-dissipating device can be fixed to a base for the element other than the heat-dissipating device to form a firm assembly.

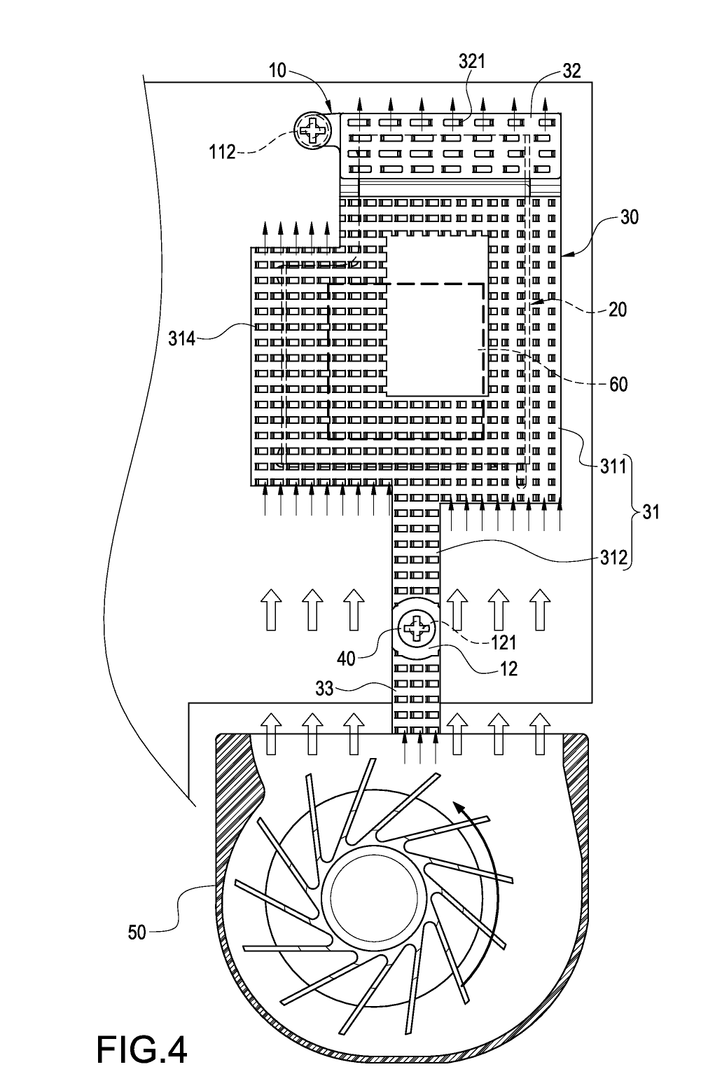

Please refer to FIG. 4. Both the frame 10 and the vapor chamber 20 are heat conductors having good heat conductivity. The rim 10 and the vapor chamber 20 of the heat-dissipating device are adhered to a heat-generating source 60, thereby conducting the heat to the heat-dissipating plate 30. The outside of the first heat-dissipating fins region 31 away from the second heat-dissipating fins region 32 is provided with a fan 50 to blow the airflow from the first heat-dissipating fins region 31 to the second heat-dissipating fins region 32. The first heat-dissipating fins region 31 is used an intake end, while the second heat-dissipating fins region 32 is used to an exhaust end. The first heat-dissipating fins region 31 having a smaller pitch of the respective first heat-dissipating fins 314 forms a large contact area for air, so that the air can absorb the heat sufficiently to thereby conduct a great amount of heat of the heat source to the outside. The second heat-dissipating fins region 32 having a larger pitch of the respective second heat-dissipating fins 321 forms large air passages, so that the air can be exhausted rapidly to achieve a good exhausting efficiency.

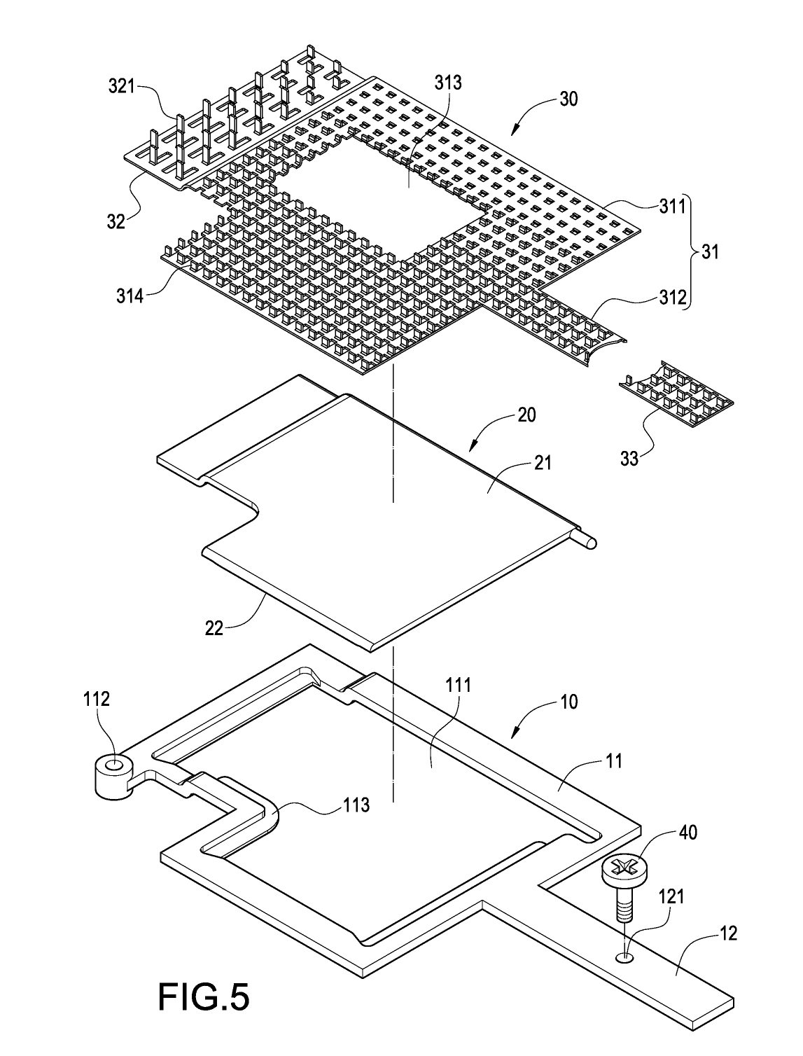

Please refer to FIG. 5. The first heat-dissipating fins region 31 and the second heat-dissipating fins region 32 of the heat-dissipating plate 30 can be formed integrally, and then both of them are pressed to form the first heat-dissipating fins 314 and the second heat-dissipating fins 321 with different heights and pitches.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A heat sink, comprising:
a frame (10);
a vapor chamber (20) fixed to the frame (10); and
a heat-dissipating plate (30) adhered to one surface of the vapor chamber (20), the heat-dissipating plate (30) having a first heat-dissipating fins region (31) and a second heat-dissipating fins region (32), the first heat-dissipating fins region (31) and the second heat-dissipating fins region (32) being composed of a plurality of first heat-dissipating fins (314) and second heat-dissipating fins (321) respectively, the pitch of the respective first heat-dissipating fins (314) of the first heat-dissipating fins region (31) being smaller than that of the respective second heat-dissipating fins (321) of the second heat-dissipating fins region (32).

2. The heat sink according to claim 1, wherein the first heat-dissipating fins region (31) and the second heat-dissipating fins region (32) are located on the same heat-dissipating passage.

3. The heat sink according to claim 2, wherein the frame (10) has a rim (11), the rim (11) is provided with a hollow portion (111), and the vapor chamber (20) is embedded into the hollow portion (111).

4. The heat sink according to claim 3, wherein the vapor chamber (20) has a lower surface (32), a bottom edge of the rim (11) extends inward to form a plurality of supporting plates (113), and the lower surface (22) is adhered to the supporting plates (1 13).

5. The heat sink according to claim 4, wherein the first heat-dissipating fins region (31) comprises a main body (311) and a rear fin (312) extending from an outer edge of the main body (311), the outer edge of the rim (11) extends to form an elongate plate (12), the vapor chamber (20) has an upper surface (21) opposite to the lower surface (22), the second heat-dissipating fins region (32) and the main body (311) are adhered to the upper surface (21) and the rim (11), and the rim (312) is adhered to the elongate plate (12).

6. The heat sink according to claim 5, further comprising a plurality of screws (40), the rim (11) being provided with a first through-hole (112), the elongate plate (12) being provided with a second through-hole (121), and the screws (40) penetrating the first through-hole (112) and the second through-hole (121) separately.

7. The heat sink according to claim 6, wherein the heat-dissipating plate (30) further comprises a third heat-dissipating fins region (33) adhered to the elongate plate (12), and the second through-hole (121) is located between the third heat-dissipating fins region (33) and the rear fin (312).

8. The heat sink according to claim 1, further comprising a fan (50) being provided outside the first heat-dissipating fins region (31) away from the second heat-dissipating fins region (32).

9. The heat sink according to claim 1, wherein a height of the first heat-dissipating fins (314) of the first heat-dissipating fins region (31) is smaller than that of the second heat-dissipating fins (321) of the second heat-dissipating fins region (32).

10. The heat sink according to claim 1, wherein heights of the first heat-dissipating fins (314) and the second heat-dissipating fins (321) decrease gradually from one side of the heat-dissipating plate (30) toward the other side thereof.
